(19) United States
(12) Patent Application Publication
(10) Pub. No.: US 2023/0207512 A1
(43) Pub. Date: Jun. 29, 2023

(54) CHIP-PACKAGE DEVICE

(71) Applicant: NANYA TECHNOLOGY CORPORATION, New Taipei City (TW)

(72) Inventors: Wu-Der YANG, Taoyuan City (TW); Chun-Huang YU, Changhua County (TW)

(21) Appl. No.: 18/179,394

(22) Filed: Mar. 7, 2023

Related U.S. Application Data
(62) Division of application No. 16/655,222, filed on Oct. 16, 2019.

(51) Int. Cl. H01L 23/00; H01L 23/498; H01L 25/065

(52) U.S. Cl. CPC H01L 24/48; H01L 23/49811; H01L 24/05; H01L 24/20; H01L 25/0657; H01L 2224/48091; H01L 2224/4813; H01L 2224/48229; H01L 2225/0651; H01L 2225/06527; H01L 2225/06565; H01L 2224/04042; H01L 2224/48106

(57) ABSTRACT

A chip-package device includes a substrate, a first chip, a first conductive layer, first wirings, and second wirings. The substrate includes a first top surface and first connection pads disposed on the first top surface. The first chip is disposed on the first top surface, and the first chip includes a second top surface and second connection pads disposed on the second top surface. The first conductive layer is disposed on the second top surface. The first wirings connect the first connection pads and the first conductive layer, and the second wirings connect the second connection pads and another side of the first conductive layer. Each of the first wirings and each of the second wirings respectively connect opposite sides of the first conductive layer.

### CROSS-REFERENCE TO RELATED APPLICATIONS

This application is a divisional application of U.S. application Ser. No. 16/655,222, filed on Oct. 16, 2019, which is herein incorporated by reference in their entireties.

### BACKGROUND

### Field of Disclosure

The present disclosure relates to a chip package device. More particularly, the present disclosure relates to a chip package with enhanced connection.

### Description of Related Art

An integrated circuit is a set of electronic circuits on one chip of semiconductor material that is normally silicon. The integration of large numbers of tiny Metal-Oxide Semiconductor (MOS) transistors into a small chip results in circuits that are orders of magnitude smaller, faster, and less expensive than those constructed of discrete electronic components. However, with the requirement of smaller and faster components in a chip, the current requirement is increasing as well. Undesired signal distortion and IR drop are caused while tiny metal wires of the chip transfer the signal with big current, and noise problem is also caused in ground connection or power connection of the chip.

### SUMMARY

The present disclosure relates in general to a chip-package device.

According to an embodiment of the present disclosure, a chip-package device includes a substrate, a first chip, a first conductive layer, first wirings, and second wirings. The substrate includes a first top surface and first connection pads disposed on the first top surface. The first chip is disposed on the first top surface, and the first chip includes a second top surface and second connection pads disposed on the second top surface. The first conductive layer is disposed on the second top surface. The first wirings connect the first connection pads and the first conductive layer, and the second wirings connect the second connection pads and the first conductive layer. Each of the first wirings and each of the second wiring respectively connect two opposite sides of the first conductive layer.

In an embodiment of the present disclosure, the chip-package device further includes third wirings. The third wirings across the first conductive layer connect the first connection pads and the second connection pads.

In an embodiment of the present disclosure, a projection area of the first conductive layer on the second top surface overlaps projection areas of the third wirings on the second top surface.

In an embodiment of the present disclosure, the first connection pads are grounded, and the second connection pads are ground voltage pads of the chip.

In an embodiment of the present disclosure, the first connection pads are connected to a power supply, and the second connection pads are power-supply pads of the chip.

In an embodiment of the present disclosure, second connection pads are disposed along a central line of the second top surface.

In an embodiment of the present disclosure, the first chip includes forth connection pads. The forth connection pads are disposed on the second top surface. The chip-package device further includes third connection pads, second conductive layer, forth wirings, and fifth wirings. The third connection pads are disposed on the first top surface, and the second conductive layer is disposed on the second top surface. The forth wirings connect the second conductive layer and the third connection pads, and the fifth wirings connect the second conductive layer and the forth connection pads. Each of the forth wirings and each of the fifth wirings respectively connect two opposite sides of the second conductive layer.

In an embodiment of the present disclosure, the chip-package device further includes sixth wirings. The sixth wirings are disposed across the second conductive layer, and connecting the third connection pads and the forth connection pads.

In an embodiment of the present disclosure, the second connection pads and the forth connection pads are located between the first conductive layer and the second conductive layer.

In an embodiment of the present disclosure, the forth connection pad is substantially aligned with the second connection pad.

In an embodiment of the present disclosure, the first connection pads are grounded, and the second connection pads are ground voltage pads of the chip. The third connection pads are connected to a power supply, and the forth connection pads are power-supply pads of the chip.

In an embodiment of the present disclosure, each of the third wirings has a portion between the first conductive layer and the second top surface.

In an embodiment of the present disclosure, the third wirings are above the first conductive layer, and the first conductive layer is located between the first wirings and the second top surface.

In an embodiment of the present disclosure, the chip-package device further comprises an adhesive layer. The adhesive layer is disposed between the first conductive layer and the third wirings, insulating the first conductive layer from the third wirings.

In an embodiment of the present disclosure, the chip-package device further includes a redistribution layers disposed on the second top surface, and each of the redistribution layers connects each of the third wirings to one of the second connection pads.

In an embodiment of the present disclosure, the chip-package device further comprises a second chip, a third conductive layer, seventh wirings, eighth wirings, and ninth wirings. The second chip is disposed on the first chip, and the second chip includes third top surface and fifth connection pads. The fifth connection pads are disposed on the third top surface, and the third conductive layer is disposed on the third top surface. The seventh wirings are disposed across the third conductive layer and connecting the first connection pads and the fifth connection pads. The eighth wirings connect the first connection pads and the third conductive layer, and the ninth wirings connect the fifth connection pads and the third conductive layer. Each of the eighth wirings and each of the ninth wirings respectively connect two opposite sides of the third conductive layer.

In the aforementioned embodiments of the present disclosure, since the first conductive layer is connected to and between the first connection pads and the second connection pads through the first wirings and the second wirings, electrical connection between the substrate and the first chip is further enhanced, and noise and distortion of signal can be further prevented.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic top view of a chip-packaged device according to an embodiment of the present disclosure;

FIG. 2 is a cross-sectional view of the chip-packaged device taken along line 2-2 shown in FIG. 1;

FIG. 3 is a cross-sectional view of an chip-packaged device according to another embodiment of the present disclosure;

FIG. 4 is a schematic top view of a chip-packaged device according to yet another embodiment of the present disclosure;

FIG. 5 is a cross-sectional view of the chip-packaged device taken along line 5-5 shown in FIG. 4;

FIG. 6 is a schematic top view of a chip-package device according to still another embodiment of the present disclosure;

FIG. 7 is a cross-sectional view of the chip-package device taken along line 7-7 shown in FIG. 6;

FIG. 8 is a cross-sectional view of the chip-package device taken along line 8-8 shown in FIG. 6;

FIG. 9 is a cross-sectional view of the chip-package device according to another embodiment of the present disclosure; and

FIG. 10 is a cross-sectional view of the chip-package device according to yet another embodiment of the present disclosure.

### DETAILED DESCRIPTION

In the figures, the thickness of layers, films, panels, regions, etc., are exaggerated for clarity. Throughout the specification, the same reference numerals denote the same component. It will be understood that when an component such as a layer, a film, a region or a substrate is referred to as “on” or “connected to” another component, intermediate components can also be present. In contrast, when a component is referred to as “directly on” or “directly connected to” another component, no intermediate component can be present. As used herein, “connected” may refer to both physical and/or electrical connections. Furthermore, “electrical connection” or “coupled” may be the presence of other components between two elements.

Reference will now be made in detail to the present embodiments of the disclosure, examples of which are illustrated in the accompanying drawings. Wherever possible, the same reference numbers are used in the drawings and the description to refer to the same or like parts.

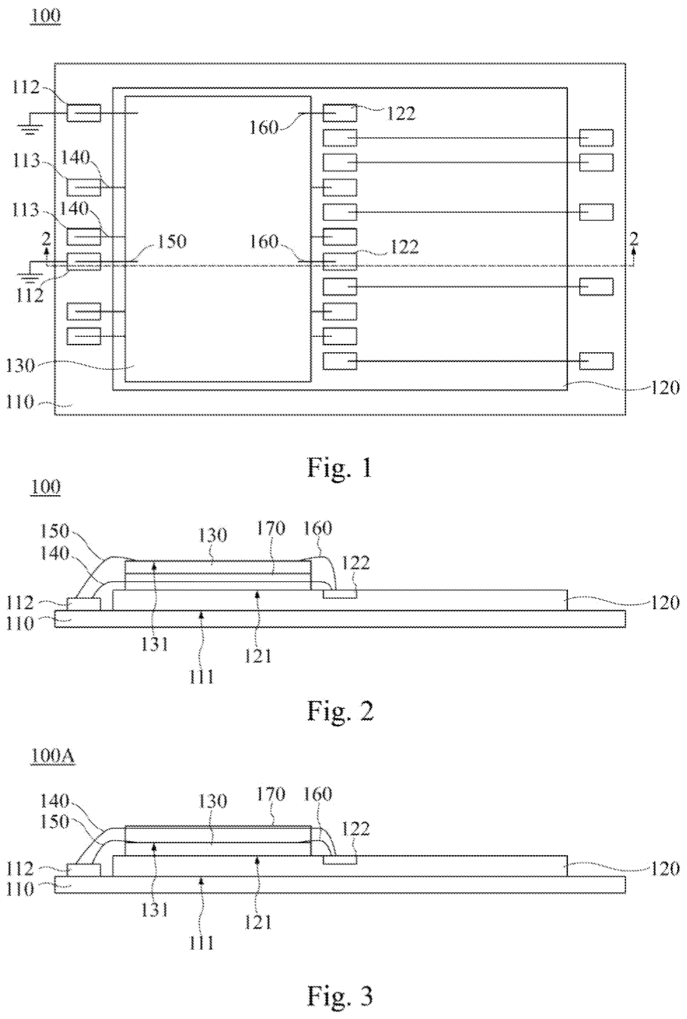

FIG. 1 is a schematic top view of a chip-package device 100 according to an embodiment of the present disclosure. FIG. 2 is a cross-sectional view of the chip-package device according to line 2-2 in FIG. 1. As shown in FIG. 1 and FIG. 2, the chip-package device 100 includes a substrate 110, a first chip 120, and a first conductive layer 130. The first chip 120 is disposed on the substrate 110, and the first conductive layer 130 is disposed on the first chip 120. In other words, the first chip 120 is located in-between the first conductive layer 130 and the substrate 110.

For example, the first chip 120 of the embodiment can be Dynamic Random Access Memory (DRAM) chip, and the substrate 110 can be Printed-Circuit Board (PCB). However, the present disclosure is not limited in this regard. Referring to FIG. 2, the substrate 110 includes a first top surface 111 and first connection pads 112, and the first connection pads 112 are disposed on the first top surface 111. The first top surface 111 of the substrate 110 faces up and mechanically supports the first chip 120.

The first top surface 111 of the substrate 110 also electrically connects the first chip 120 disposed thereon. The chip-package device 100further includes first conductive layer 130, first wirings 150, and second wirings 160. The first chip 120 includes a second top surface 121 and second connection pads 122 that are disposed on the second top surface 121. Furthermore, in this embodiment, the first conductive layer 130 is disposed on the second top surface 121, and the first wirings 150 and the second wirings 160 connect two opposite sides of the first conductive layer 130, respectively.

Referring to FIG. 2, the first wiring 150 connects the first connection pad 112 and the first conductive layer 130, and the second wiring 160 connects the first conductive layer 130 and the second connective pad 122, while a conductive top surface 131 of the first conductive layer 130 provide a wide connection area for the first wiring 150 and the second wiring 160. Furthermore, in the chip-package device 100 of the embodiment, signal with big current can transmit via the first conductive layer 130, and distortion and noise of the signal will be reduced.

In some embodiments, the chip-package device 100 can further include third wirings 140. Each of the third wirings 140 has two opposite ends respectively connect one of the first connection pads 112 on the first top surface 111 and one of the second connection pads 122 on the second top surface. The third wiring 140 can be thin wire made of metal such as gold, and the material of the first conductive layer 130 can include metal such as copper or aluminum, or any other metal possessing low resistivity, and the thickness of the first conductive layer 130 falls in a range from 60 micrometer to 100 micrometer. Therefore, the first conductive layer 130 of the embodiment can enhance the connection between the substrate 110 and the first chip 120. In other words, the third wiring 140 is a branch of parallel circuit between the first connection pad 112 and the second connection pad 122, and the combination of the first wiring 150, the first conductive layer 130, and the second wiring 160 is another branch of the parallel circuit. Moreover, compared with the third wiring 140 having lower thickness, the first conductive layer 130 provides electrical connection with lower electrical resistance. As a result of such a configuration, IR drop can be further prevented in the chip-package device 100 of the embodiment.

To be specific, in the embodiment, the second connection pads 122 are disposed along a central line of the second top surface 121. Projection area of the first conductive layer 130 on the second top surface 121 overlaps projection areas of the third wirings 140. For example, referring to FIG. 1, the third wirings 140 further connects the connection pads 113 which provide signal that is different from the signal provided by the first connection pads 112. Compared with the third wirings 140, the first conductive layer 130 is disposed on a larger distribution area with larger width on the second top surface 121 of the first chip 120, so as to improve connection between the first connection pads 112 and second connection pads 122.

Referring to FIG. 2, in the embodiment, fabricating the chip-package device 100 includes disposing the first chip 120 on the substrate 110; forming the third wirings 140 connecting and between the first connection pads 112 and the second connection pads 122; disposing the first conductive layer 130 on the first chip 120; forming the first wirings 150 connecting and between the first connection pads 112 and the first conductive layer 130; and forming the second wirings 160 connecting and between the first conductive layer 130 and the second connection pads 122.

Moreover, the chip-package device 100 of the embodiment includes an adhesive layer 170, which is disposed before disposing the first conductive layer 130. Referring to FIG. 2, the adhesive layer 170 is disposed between the first conductive layer 130 and the third wiring 140, and the adhesive layer 170 insulates the first conductive layer 130 from the third wiring 140. In other words, the adhesive layer 170 includes insulating material, and the adhesive layer 170 between the first conductive layer 130 and the third wirings 140 can prevent short circuit.

As a result, the third wirings 140 of the embodiment pass through the area between the first conductive layer 130 and the second top surface 121, and the third wirings 140 is covered by the adhesive layer 170 while the adhesive layer 170 is below the first conductive layer 130. In other words, each of the third wirings 140 of the embodiment has a portion between the first conductive layer 130 and the third wirings 140. However, the present disclosure is not limited to the above connection.

FIG. 3 is a cross-sectional view of a chip-packaged device 100A according to another embodiment of the present disclosure. Referring to FIG. 3, fabricating the chip-package device 100A of the embodiment includes disposing the first chip 120 on the substrate 110; disposing the first conductive layer 130 on the first chip 120; forming the first wirings 150 connecting and between the first connection pads 112 and the first conductive layer 130; forming the second wirings 160 connecting and between the first conductive layer 130 and the second connection pads 122; and forming the third wirings 140 connecting and between the first connection pads 112 and the second connection pads 122.

Therefore, the third wirings 140 of the chip-packaged device 100A cross over the first conductive layer 130, and the first conductive layer 130 is disposed between the third wiring 140 and the second top surface 121 of the first chip 120. In other words, the third wirings 140 are above the first conductive layer 130. In this embodiment, the adhesive layer 170 can be disposed on the conductive top surface 131 of the first conductive layer 130, so as to insulate the first conductive layer 130 from the third wiring 140.

Referring to FIG. 1, in the embodiment, the first connection pads 112 are grounded or connected to a ground voltage supply of a power supply, and the second connection pads 122 are ground voltage pads of the first chip 120, so as to prevent IR shift or distortion. In other word, the first conductive layer 130 of the embodiment can transmit ground signal between the substrate 110 and the first chip 120.

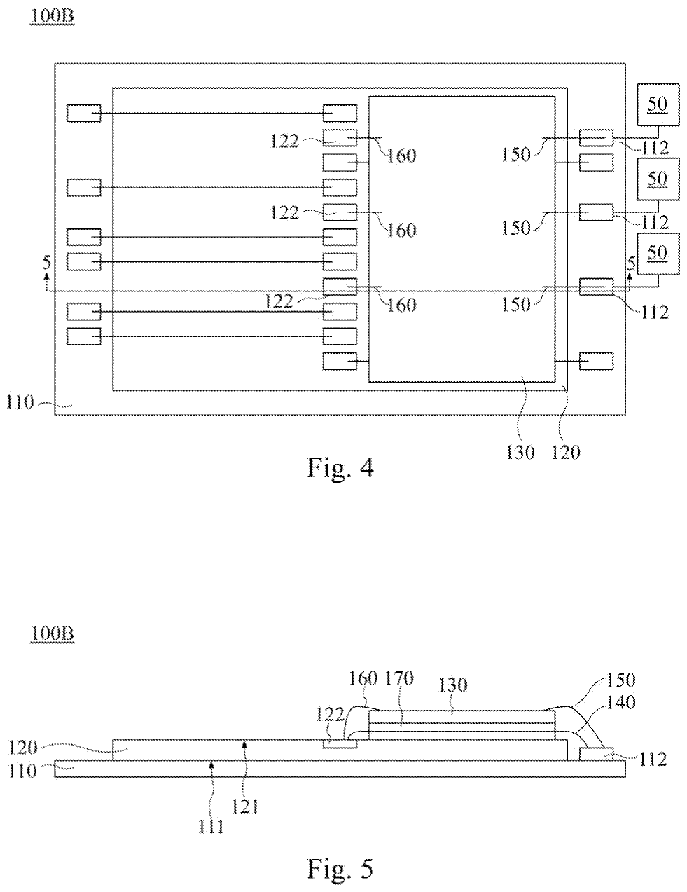

In another embodiment of the present disclosure, the first conductive layer 130 can also transmit power signal such as Vdd between the substrate 110 and the first chip 120. FIG. 4 is a schematic top view of a chip-package device 100B according to yet another embodiment of the present disclosure. FIG. 5 is a cross-sectional view of the chip-package device 100B according to line 5-5 shown in FIG. 4. The chip-package 1008 includes the substrate 110, the first connection pads 112 on the first top surface 111, the first chip 120, the second connection pads 122 on the second top surface 121, the first conductive layer 130, the third wirings 140, the first wirings 150, and the second wirings 160 similar to those of the aforementioned chip-package device 100. In addition, the adhesive layer 170 of the chip-package device 100B can also be disposed between the first conductive layer 130 and the second top surface 121, so as to insulate the first conductive layer 130 from the third wiring 140.

Moreover, the first conductive layer 130 of the chip-package device 100B is disposed on another area of the second top surface 121 of the first chip 120 due to the positions of the first connection pads 112. In this embodiment, each of the first connection pads 112 is connected to a power supply 50, and the second connection pads 122 are power-supply pads of the first chip 120. In other words, the first conductive layer 130, the first wiring 150, and the second wiring 160 can transmit the Vdd signal between the substrate 110 and the first chip 120, so as to prevent IR shift and signal distortion.

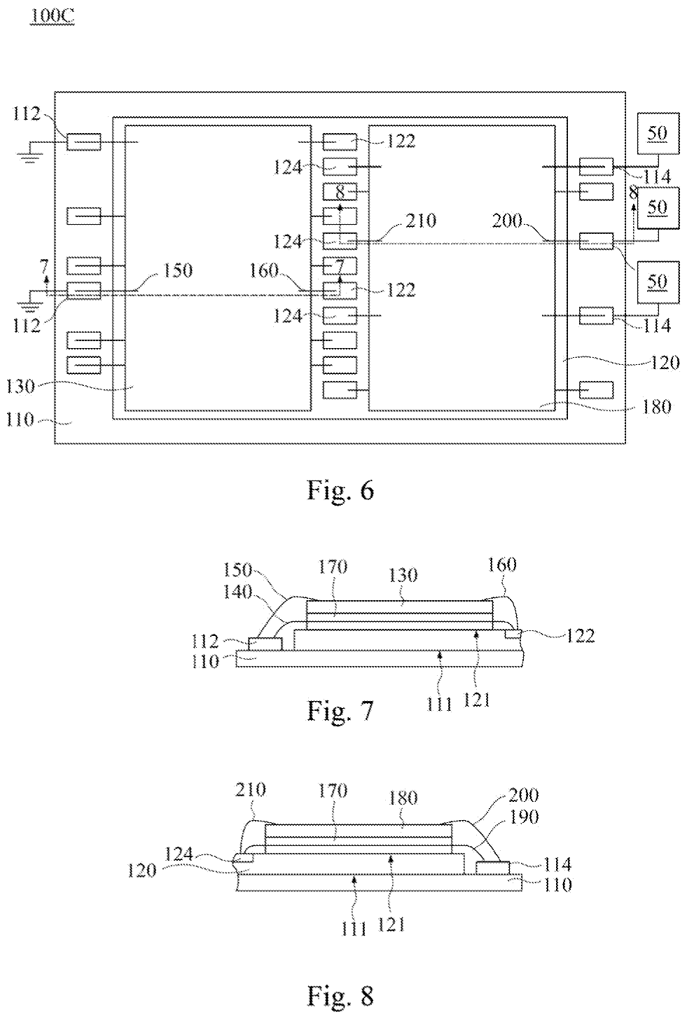

In still another embodiment of the present disclosure, the chip-package device can further include another conductive layer on the first chip. FIG. 6 is a schematic top view of a chip-package device 100C according to still another embodiment of the present disclosure. FIG. 7 is a cross-sectional view of the chip-package device 100C according to line 7-7 shown in FIG. 6. FIG. 8 is a cross-sectional view of the chip-package device 100C according to line 8-8 shown in FIG. 6. In this embodiment, the chip-package device 100C includes substrate 110, the first connection pad 112, the first chip 120, the second connection pad 122, the third wiring 140, the first wiring 150, and the second wiring 160, which is similar to the chip-package device 100 of the above embodiment.

Moreover, the chip-package device 100C further include a second conductive layer 180 disposed on the second top surface121 of the first chip 120, and the first chip 120 includes forth connection pads 124 disposed on the second top surface 121. Referring to FIG. 6, the second connection pads 122 are centrally arranged on the second top surface 121, and the distribution area of the second connection pads 122 and the forth connection pads 124 are located between the projection area of the first conductive layer 130 on the second top surface 121 and the projection area of the second conductive layer 180 on the second top surface 121.

In other words, the second connection pads 122 and the forth connection pads 124 on the first chip 120 are located between the first conductive layer 130 and the second conductive layer 180, and the forth connection pads 124 are aligned with the second connection pads 122. To be specific, the distribution areas of the first conductive layer 130 and the second conductive layer 180 of the embodiment do not overlap with each other. Stated differently, the first conductive layer 130 is spaced apart from the second conductive layer 180.

Moreover, the chip-package device 100C further includes the third connection pads 114, sixth wirings 190, forth wirings 200, and fifth wirings 210. The third connection pads 114 of the chip-package device 100C are disposed on the first top surface 111 of the substrate 110, and each of the sixth wirings 190 connects one of third connection pads 114 and one of the forth connection pads 124. The forth wiring 200 is connected to and between the third connection pad 114 and a side of the second conductive layer 180, and the fifth wiring 210 is connected to and between another side of the second conductive layer 180 and the forth connective pad 124. In other words, the sixth wiring 190 and the combination of the forth wiring 200, the second conductive layer 180, and the fifth wiring 210 form a parallel circuit between the third connection pad 114 and the forth connection pad 124. Therefore, both the first conductive layer 130 and the second conductive layer 180 of the chip-package device 100C can provide a proper electrical connection, and being able to transmit different signals, respectively.

For example, in the embodiment, the first connection pads 112 are grounded, and the second connection pad 122 are ground voltage pads of the first chip 120. Each of the third connection pads 114 is connected to a power supply 50, and the forth connection pads 124 are power-supply pads of the first chip 120. In other words, in this embodiment, the first conductive layer 130 can transmit ground (GND) signal between the substrate 110 and the first chip 120, and the second conductive layer 180 can transmit Vdd (power) signal between the substrate 110 and the first chip 120, so as to reduce the IR shift and signal distortion in both signals.

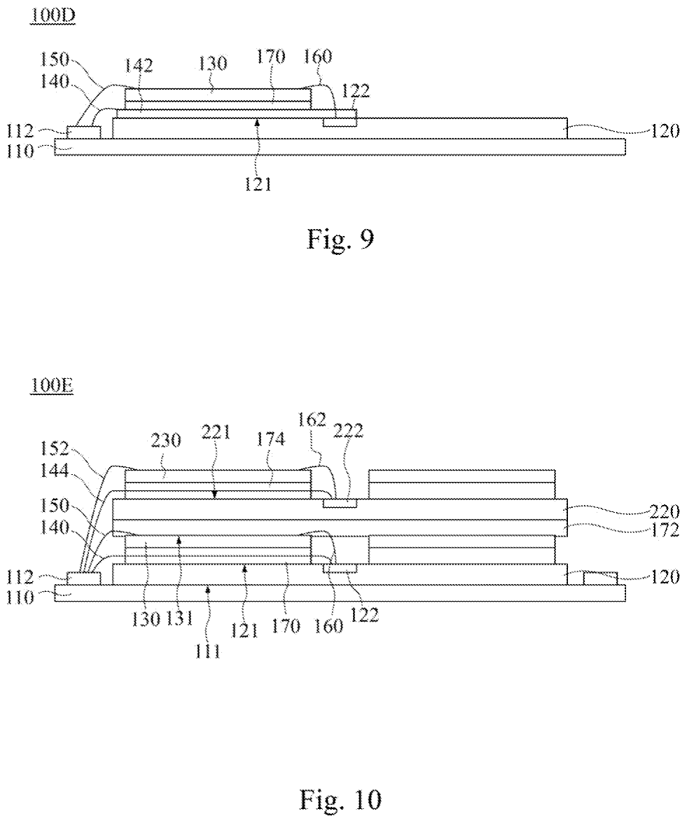

In another embodiment of the present disclosure, chip-package device can include redistribution layer (RDL). In the embodiment, the redistribution layer is an extra metal layer on a first chip that makes the second connection pads of the first chip are available in other locations of the first chip, for better access to the second connection pads where necessary. FIG. 9 is a cross-sectional view of the chip-package device 100D according to the embodiment of the present disclosure. The chip-package device 100D includes the substrate 110, the first chip 120, the first conductive layer 130, the first wiring 150, and the second wiring 160, which is similar to the chip-package device 100 of the above embodiment. Moreover, the chip-package device 100D includes redistribution layers 142, being disposed on the second top surface 121 of the first chip 120, and the redistribution layers142 connect the third wirings 140 and the second connection pads 122. While every redistribution layer 142 of the embodiment is connecting one of the first connection pad 112 to one of the second connection pad 122, the first conductive layer 130 with larger dimension can provide a better connection between the substrate 110 and the first chip 120.

The chip-package device of yet another embodiment of the present disclosure can be implemented on a stacked-type chip package device. A stacked-type chip package device is a semiconductor package device where a three-dimensional package technology is employed to vertically stack a plurality of chips, being able to apply to storage device such as memory module, memory cards, portable flash disks, and so forth.

FIG. 10 is a cross-sectional view of the chip-package device 100E according to the embodiment of the present disclosure. Referring to FIG. 10, the chip-package device 100E includes the substrate 110, the first connection pad 112, the first chip 120, the second connection pad 122, the first conductive layer 130, the third wirings 140, the first wirings 150, and the second wirings 160, which is similar to the chip-package device 100 of the above embodiment. Moreover, the chip-package device 100E further includes a second chip 220, a third conductive layer 230, seventh wirings 144, eighth wirings 152, and ninth wirings 162.

In this embodiment, the second chip 220 is disposed on the first chip 120, and the second chip 220 includes a third top surface 221 and fifth connection pads 222 disposed on the third top surface 221 of the second chip 220. The third conductive layer 230 is disposed on the third top surface 221 of the second chip 220. Furthermore, an adhesive layer 174 is disposed on the second chip 220 and between the third top surface 221 and the third conductive layer 230. The adhesive layer 172 is disposed on the first conductive layer 130 and between the conductive top surface 131 and the second chip 220.

Referring to FIG. 10, the seventh wiring 144 connects the first connection pad 112 and the fifth connection pad 222, and the eighth wiring 152 connects the first connection pad 112 and a side of the third conductive layer 230, and the ninth wiring 162 connects the fifth connection pad 222 and another side of the third conductive layer 230, so as to provide enhanced electrical connection for both the first chip 120 and the second chip 220.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the device of the present disclosure without departing from the scope or spirit of the disclosure. In view of the foregoing, it is intended that the present disclosure cover modifications and variations of this disclosure provided they fall within the scope of the following claims.

What is claimed is:

1. A chip-package device, comprising:
a substrate comprising a first top surface and a first connection pad disposed on the first top surface;
a first chip disposed directly on the first top surface of the substrate, the first chip comprising a second top surface and a second connection pad disposed directly on the second top surface;
a first conductive layer disposed on the second top surface of the first chip;
a first wiring connecting the first connection pad to the first conductive layer;
a second wiring connecting the second connection pad to the first conductive layer, wherein the first wiring and the second wiring are respectively connected to two opposite sides of the first conductive layer;
a redistribution layer disposed on the second top surface of the first chip and connected to the second connection pad; and
a third wiring connecting the first connection pad to the redistribution layer.

2. The chip-package device of claim 1, wherein the redistribution layer extends to a top surface of the second connection pad.

3. The chip-package device of claim 1, wherein the redistribution layer is between the first conductive layer and the second top surface of the first chip.

4. The chip-package device of claim 1, wherein the redistribution layer is a metal layer.

5. The chip-package device of claim 1, further comprising:
an adhesive layer disposed between the first conductive layer and the redistribution layer, wherein the adhesive layer insulates the first conductive layer from the redistribution layer.

6. The chip-package device of claim 5, wherein the adhesive layer comprises insulating material.

7. The chip-package device of claim 1, wherein the first conductive layer is copper or aluminum.

8. The chip-package device of claim 1, wherein the third wiring is made of gold.

9. The chip-package device of claim 1, wherein the second connection pad is covered with the redistribution layer.

10. The chip-package device of claim 1, wherein from a cross-sectional view, a lateral dimension of the first conductive layer is less than a lateral dimension of the redistribution layer.

11. The chip-package device of claim 1, wherein the first wiring comprises two ends in contact with the first connection pad and the first conductive layer, respectively.

12. The chip-package device of claim 1, wherein the second wiring comprises two ends in contact with the second connection pad and the first conductive layer, respectively.

13. The chip-package device of claim 1, wherein the third wiring comprises two ends in contact with the redistribution layer and the first connection pad, respectively.

14. The chip-package device of claim 1, wherein the redistribution layer is at a position higher than the second connection pad.

15. The chip-package device of claim 1, wherein an end of the second wiring connected to the second connection pad is at a position lower than an end of the third wiring connected to the redistribution layer.

16. The chip-package device of claim 1, wherein the first connection pad is spaced apart from the first chip and the redistribution layer by a gap.

17. The chip-package device of claim 1, wherein the redistribution layer laterally extends beyond a side surface of the first conductive layer.

18. The chip-package device of claim 1, wherein the first connection pad is grounded, and the second connection pad is a ground voltage pad of the first chip.

19. The chip-package device of claim 1, wherein the first connection pad is connected to a power supply, and the second connection pad is a power-supply pad of the first chip.

20. The chip-package device of claim 1, wherein the second connection pad is disposed along a central line of the second top surface.
